(19) United States
(12) Patent Application Publication
(10) Pub. No.: US 2026/0096498 A1
(43) Pub. Date: Apr. 2, 2026

(54) SURFACE-MOUNT-TYPE OPTICAL MODULE AND CO-PACKAGED OPTICS SWITCH ASSEMBLY INCLUDING THE SAME

(71) Applicant: ELECTRONICS AND TELECOMMUNICATIONS RESEARCH INSTITUTE, Daejeon (KR)

(72) Inventors: Sangjin KWON, Daejeon (KR); Jong Jin LEE, Daejeon (KR); Eun Kyu KANG, Daejeon (KR); Won-Bae KWON, Daejeon (KR); Soo Yong JUNG, Daejeon (KR); HaeChung KANG, Daejeon (KR); Myunghwan KIM, Daejeon (KR); Dae Woong MOON, Daejeon (KR); GYE SUL CHO, Daejeon (KR)

(73) Assignee: ELECTRONICS AND TELECOMMUNICATIONS RESEARCH INSTITUTE, Daejeon (KR)

(21) Appl. No.: 19/345,607

(22) Filed: Sep. 30, 2025

(30) Foreign Application Priority Data
Oct. 2, 2024 (KR) 10-2024-0134093
Aug. 26, 2025 (KR) 10-2025-0119195

(51) Int. Cl. H01L 23/498; H01L 21/48; H01L 23/15; H01L 23/538; H01L 25/18

(52) U.S. Cl. CPC H10W 90/701; H10W 70/093; H10W 70/611; H10W 70/65; H10W 70/692; H10W 90/00; H10W 90/401

(57) ABSTRACT

A surface-mount-type optical module is mounted on a system board. The surface-mount-type optical module includes a glass interposer, a plurality of solder pads formed in a two-dimensional (2D) array of a matrix form on a lower surface of the glass interposer and bonded to the system board, and an optical engine mounted on the glass interposer and electrically connected to the plurality of solder pads by through glass vias and interposer redistribution layers formed in the glass interposer, wherein each of the plurality of solder pads is formed at a position offset by a predefined distance in a horizontal direction not to overlap the through glass vias in a vertical direction.

### CROSS-REFERENCE TO RELATED APPLICATIONS

This application claims the benefit of the Korean Patent Application No. 10-2024-0134093 filed on Oct. 2, 2024, and 10-2025-0119195 filed on Aug. 26, 2025, which is hereby incorporated by reference as if fully set forth herein.

### BACKGROUND

### Field of the Invention

The present disclosure relates to a surface-mount-type optical module, and more particularly, to a surface-mount-type optical module based on a co-packaged optics (CPO) structure, which may be mounted on a switch application specific integrated circuit (ASIC) system board for data center by using a soldering process.

### Discussion of the Related Art

Recently, as service industries based on hyper-connected intelligent infrastructure such as 5G network and artificial intelligence (AI) have rapidly advanced, the amount of data traffic is increasing rapidly. Furthermore, the importance of a cloud-based operation capability has increased based on the activation of a cloud service, and thus, cloud service providers are actively facilitating the high advancement of network equipment in data centers.

Particularly, due to the spread of an AI service, a data center network is changed to a network interconnection structure based on high performance computing (HPC) in a conventional data center structure, and thus, the importance of optical communication technology having low power and low delay characteristics is increasing. In essential factors for reducing the operation cost and carbon emission of data centers, the low power consumption of optical modules is attracting much attention as necessary requirements.

Moreover, in the effort to improve the energy efficiency of whole system, the low power consumption of switch application specific integrated circuit (ASIC) devices which are a core part of network equipment is being continuously realized by applying an ultra-fine process of 5 nm or less. However, as a system bandwidth increases, the importance of power consumption of optical modules in a whole system is increasing all the more.

In such a background, various attempts for closely placing a switch ASIC and an optical module have been performed as a method of reducing the power consumption of optical modules and enhancing a transmission speed. Therefore, unlike a conventional pluggable optics method, on-board optics technology which couples an optical module to a system board through a socket method has been introduced. However, due to a problem of signal loss and distortion occurring in a process where a high frequency signal passes through a socket, corresponding technology has a limitation in implementing a next-generation optical module requiring high speed and low power characteristics.

In technology for solving such problems, co-packaged optics (CPO) technology where a switch ASIC and an optical module are mounted on the same substrate together is attracting much attention. CPO technology may minimize a physical distance between a switch ASIC and an optical module, and thus, may decrease radio frequency (RF) signal loss and distortion. As a result, CPO technology is a structure which is favorable for enhancing a transmission speed and reducing power consumption. Also, CPO technology is driven based on a direct drive method by using a driver embedded in a switch ASIC, and thus, may minimize the power consumption of a digital signal processor (DSP) device.

However, CPO method couples an optical module to a board by using a soldering process, and due to this, has a problem where replacement is difficult when a breakdown occurs, and the flexibility of maintenance and repair is reduced. Conventional pluggable optics or socket-based method is relatively easy to replace an optical module at a site, but in a CPO method, the replacement of an optical module is complicated, and depending on the case, a situation where a whole switch ASIC system board should be replaced may occur, causing the burden in terms of operating expenditure (OPEX).

Therefore, it is required to develop a surface-mount-type optical module where maintenance/repair and module replacement are possible at a site.

### SUMMARY

An aspect of the present disclosure is directed to providing a detachable surface-mount-type optical module which may include a stack-type glass interposer and an input/output solder pad of a two-dimensional (2D) array so as to enhance a transmission speed per unit channel and more increase a whole data transmission capacity through channel parallelization, so that a merit of co-packaged optics (CPO) technology is maintained, maintenance/repair and optical module replacement are easily performed, and an increase in a data transmission capacity needed for optical modules is adapted.

To achieve these and other advantages and in accordance with the purpose of the invention, as embodied and broadly described herein, there is provided a surface-mount-type optical module mounted on a system board, the surface-mount-type optical module including: a glass interposer; a plurality of solder pads formed in a two-dimensional (2D) array of a matrix form on a lower surface of the glass interposer and bonded to the system board; and an optical engine mounted on the glass interposer and electrically connected to the plurality of solder pads by through glass vias and interposer redistribution layers formed in the glass interposer, wherein each of the plurality of solder pads is formed at a position offset by a predefined distance in a horizontal direction not to overlap the through glass vias in a vertical direction.

In an embodiment, each of the plurality of solder pads may be formed at a position offset in the horizontal direction not to overlap the interposer redistribution layers in a vertical direction.

In an embodiment, the plurality of solder pads may be electrically and mechanically bonded to a surface of the system board by a plurality of solder bumps, and a laser beam passing through the glass interposer may reach the plurality of solder pads without interference of the interposer redistribution layers, and laser energy absorbed by the plurality of solder pads may melt the plurality of solder bumps to electrically and mechanically bond the plurality of solder pads to the system board.

In an embodiment, the laser beam may include a plurality of laser beams output in parallel.

In an embodiment, the laser beam may include a homogenized collimated laser beam output from a homogenized collimated laser beam irradiation system.

In an embodiment, each of the plurality of solder bumps used for bonding the plurality of solder pads to the system board may be a low temperature solder bump, and each of the plurality of solder bumps used for bonding the through glass vias formed in the glass interposer may be a high temperature solder bump.

In an embodiment, the high temperature solder bump may be melted within a first temperature range, and the low temperature solder bump may be melted within a second temperature range which is lower than the first temperature range.

In another aspect of the present invention, there is provided a co-packaged optics switch assembly including: a system board; a surface-mount-type optical module mounted on the system board; and a switch application specific integrated circuit (ASIC) mounted on the system board and electrically connected to the surface-mount-type optical module by a redistribution layer and a through via formed in the system board, wherein the surface-mount-type optical module includes: a glass interposer; a plurality of solder pads formed in a two-dimensional (2D) array of a matrix form on a lower surface of the glass interposer and bonded to the system board; and an optical engine mounted on the glass interposer and electrically connected to the plurality of solder pads by through glass vias and interposer redistribution layers formed in the glass interposer, and each of the plurality of solder pads is formed at a position offset by a predefined distance in a horizontal direction not to overlap the through glass vias in a vertical direction.

According to embodiments of the present disclosure, the implementation of high-density integration and the enhancement of maintenance/repair may be simultaneously accomplished in a CPO system environment, based on a laser soldering structure where a surface-mount-type optical module including a solder pad formed in a 2D array of a matrix form may be easily bonded to a system board.

Particularly, based on a solder pad structure arranged at an offset position and laser transmission through an optically-transparent glass interposer, a local heating process using a multi-channel laser beam or a homogenized collimated laser beam may be possible, and thus, the individual attachment/detachment and replacement of a surface-mount-type optical module may be precisely performed.

Therefore, only a specific optical module may be selectively removed and replaced in a narrow space without needing to replace a whole system board or a switch ASIC even when an optical module is broken down, and thus, OPEX and convenience for the maintenance/repair of a CPO system may be considerably enhanced.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

FIG. 1 is a plan view of a co-packaged optics switch assembly according to embodiments of the present disclosure when seen from above.

FIG. 2 is an enlarged perspective view of a region A of FIG. 1.

FIG. 3 is a vertical cross-sectional view of the region A of FIG. 1 and is a diagram illustrating in more detail a signal path between a switch application specific integrated circuit (ASIC) and a surface-mount-type optical module.

FIG. 4 is a perspective view illustrating an array structure of solder pads and a signal path of a surface-mount-type optical module in the signal path between the switch ASIC and the surface-mount-type optical module illustrated in FIG. 3.

FIG. 5 is a plan view of the array structure of the solder pads illustrated in FIG. 4 when seen from above.

FIG. 6A is a plan view illustrating a solder pad of 3×6 array according to embodiments of the present disclosure, and FIG. 6B is a plan view illustrating a solder pad of 3×8 array according to embodiments of the present disclosure.

FIG. 7A is a side view illustrating a form where an optical engine is disposed on a glass interposer, based on a solder pad structure of 3×6 array illustrated in FIG. 6A, and FIG. 7B is a side view illustrating a form where an optical engine is disposed on a glass interposer, based on a solder pad structure of 3×8 array illustrated in FIG. 6B.

FIG. 8 is a side view for describing a bonding process between a system board and a surface-mount-type optical module according to embodiments of the present disclosure.

FIG. 9 is a side view for describing a bonding process between a system board and a surface-mount-type optical module according to other embodiments of the present disclosure.

### DETAILED DESCRIPTION OF THE INVENTION

Reference will now be made in detail to the exemplary embodiments of the present disclosure, examples of which are illustrated in the accompanying drawings. Wherever possible, the same reference numbers will be used throughout the drawings to refer to the same or like parts.

In the following description, the technical terms are used only for explaining a specific embodiment while not limiting the present invention. The terms of a singular form may include plural forms unless referred to the contrary. The meaning of ‘comprise’, ‘include’, or ‘have’ specifies a property, a region, a fixed number, a step, a process, an element and/or a component but does not exclude other properties, regions, fixed numbers, steps, processes, elements and/or components.

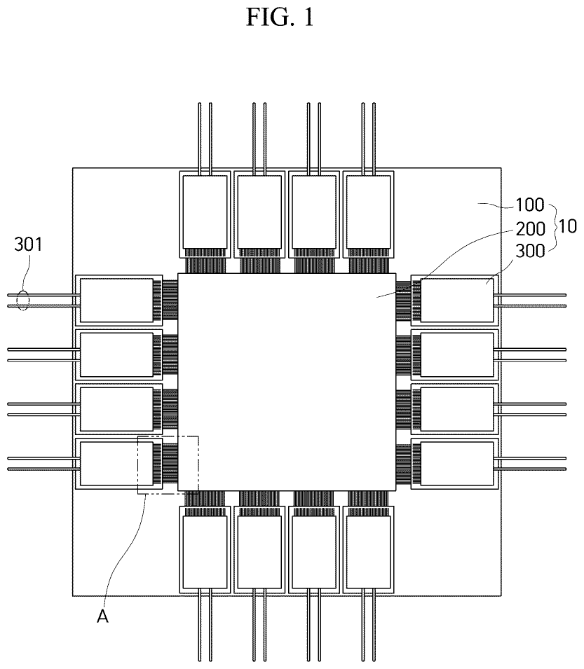

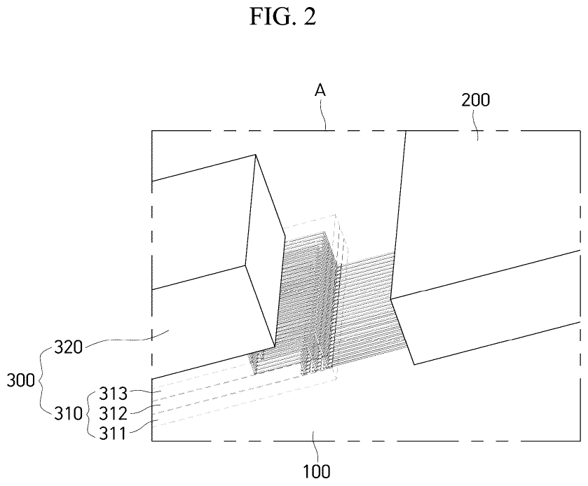

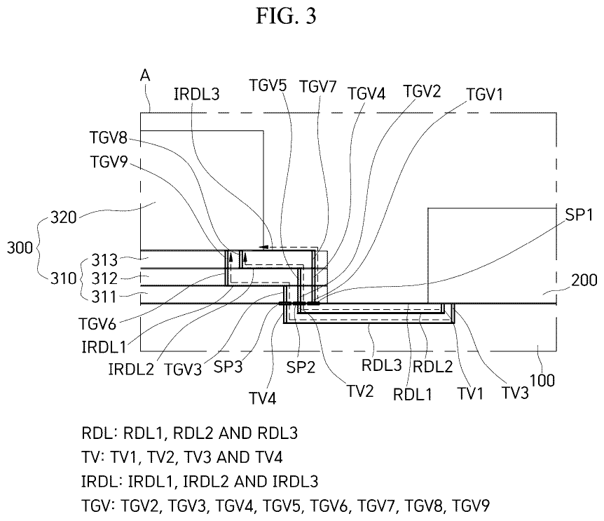

FIG. 1 is a plan view of a co-packaged optics switch assembly (hereinafter referred to as a CPO switch assembly) 10 according to embodiments of the present disclosure when seen from above. FIG. 2 is an enlarged perspective view of a region A of FIG. 1. FIG. 3 is a vertical cross-sectional view of the region A of FIG.

First, referring to FIGS. 1 and 2, the CPO switch assembly 10 according to embodiments of the present disclosure may include a system board 100, a switch application specific integrated circuit (ASIC) 200, and a surface-mount-type optical module 300. The switch ASIC 200 and the surface-mount-type optical module 300 may be mounted on the system board 100 together, and thus, the CPO switch assembly 10 may be configured in a CPO structure so as to implement high-speed signal transmission and low power consumption.

The system board 100 may be a board with all circuits mounted thereon, and various circuit elements may be fixed and disposed thereon. The switch ASIC 200 may be mounted on the system board 100, and the switch ASIC 200 may be a core semiconductor chip which performs a network switching function and may perform a plurality of high-speed data processing and a packet forwarding function.

A plurality of surface-mount-type optical modules 300 may be arranged at a certain interval and may be mounted on the switch ASIC 200. Each of the surface-mount-type optical modules 300, as illustrated in FIG. 2, may be configured to include an optically-transparent interposer 310 and an optical engine 320 mounted thereon. The interposer 310, for example, may be formed of a transparent material such as glass or sapphire and may be configured to include a plurality of interposers 311 to 313 which are sequentially stacked. Hereinafter, an example where an interposer is limited to a glass interposer will be described.

The optical engine 320 may be configured to convert an electrical signal into an optical signal or convert an optical signal into an electrical signal and may be connected to the switch ASIC 200 through a direct high-speed interface.

In FIG. 1, a reference numeral 301 may refer to an optical fiber, and the optical fiber 301 may perform a function of an input/output (I/O) port which transfers an optical signal, received from an external optical communication network, to the optical engine 320, or transfers an optical signal, generated by the optical engine 320, to the external optical communication network.

FIG. 3 is a vertical cross-sectional view of the region A of FIG. 1 and is a diagram illustrating in more detail a signal path between a switch ASIC and a surface-mount-type optical module.

Referring to FIG. 3, a signal path between the switch ASIC 200 and the surface-mount-type optical module 300 may include a system board-side signal path and an interposer-side signal path electrically connected to the system board-side signal path.

The system board-side signal path may be formed in an inner portion and a surface of the system board 100. In embodiments, the system board-side signal path may include a redistribution layer RDL and a through via TV.

In embodiments, the redistribution layer RDL may include a first redistribution layer RDL1, a second redistribution layer RDL2, and a third redistribution layer RDL3. The first redistribution layer RDL1 may be formed on an upper surface of the system board 100. The second redistribution layer RDL2 may be formed in the system board 100. The third redistribution layer RDL3 may be formed under the second redistribution layer RDL2, in the system board 100.

In embodiments, the through via TV may be formed in the system board 100 and may include a first through via TV1, a second through via TV2, a third through via TV3, and a fourth through via TV4.

An upper end portion of the first through via TV1 may be electrically connected to the switch ASIC 200, and a lower end portion thereof may be electrically connected to one end portion of the second redistribution layer RDL2. The other end portion of the second redistribution layer RDL2 may be electrically connected to a lower end portion of the second through via TV2, and an upper end portion of the second through via TV2 may be electrically connected to the interposer-side signal path. Accordingly, one signal path which electrically connects the switch ASIC 200 to the surface-mount-type optical module 300 may be formed.

An upper end portion of the third through via TV3 may be electrically connected to the switch ASIC 200, and a lower end portion thereof may be electrically connected to one end portion of the third redistribution layer RDL3. The other end portion of the third redistribution layer RDL3 may be electrically connected to a lower end portion of the fourth through via TV4, and an upper end portion of the fourth through via TV4 may be electrically connected to the interposer-side signal path. Accordingly, another signal path which electrically connects the switch ASIC 200 to the surface-mount-type optical module 300 may be formed.

Moreover, because the first redistribution layer RDL1 is formed on the upper surface of the system board 100, one end portion of the first redistribution layer RDL1 may be directly and electrically connected to the switch ASIC 200 without passing through the through via TV, and the other end portion thereof may be directly and electrically connected to the interposer-side signal path without passing through the through via TV.

The interposer-side signal path may be formed in an inner portion and a surface of the glass interposer 310 included in the surface-mount-type optical module 300. In embodiments, the interposer-side signal path may include a solder pad SP, an interposer redistribution layer IRDL, and a through glass via TGV.

In embodiments, the solder pad SP may include a first solder pad SP1, a second solder pad SP2, and a third solder pad SP3. The glass interposer 310 may include a first glass interposer 311, a second glass interposer 312, and a third glass interposer 313, which are sequentially stacked. The first to third solder pads SP1 to SP3 may be formed in a two-dimensional (2D) array of a matrix form on the upper surface of the system board 100 and/or a lower surface of the first glass interposer 311 formed at a lowermost portion. The first solder pad SP1 may be electrically connected to the other end portion of the first redistribution layer RDL1 formed on the upper surface of the system board 100 through a soldering process, and the second solder pad SP2 may be electrically connected to an upper end portion of the second through via TV2 formed in the system board 100 through a soldering process. Also, the third solder pad SP3 may be electrically connected to an upper end portion of the fourth through via TV4 formed in the system board 100.

In embodiments, the interposer redistribution layer IRDL may include a first interposer redistribution layer IRDL1, a second interposer redistribution layer IRDL2, and a third interposer redistribution layer IRDL3, and the through glass via TGV may include first to ninth through glass vias TGV1 to TGV9.

The first interposer redistribution layer IRDL1 may be formed between the first glass interposer 311 and the second glass interposer 312 stacked thereon, and the second interposer redistribution layer IRDL2 may be formed between the second glass interposer 312 and the third glass interposer 313 stacked thereon. Also, the third interposer redistribution layer IRDL3 may be formed on an upper surface of the third glass interposer 313.

The first to third through glass vias TGV1 to TGV3 may pass through an inner portion of the first glass interposer 311, and the fourth to sixth through glass vias TGV4 to TGV6 may pass through an inner portion of the second glass interposer 312. Also, the seventh to ninth through glass vias TGV7 to TGV9 may pass through an inner portion of the third glass interposer 313.

Lower end portions of the first to third through glass vias TGV1 to TGV3 may be respectively and electrically connected to the first to third solder pads SP1 to SP3. In this case, each of the first to third solder pads SP1 to SP3 may be formed at an offset position so as not to be aligned with a corresponding through glass via of the first to third through glass vias TGV1 to TGV3 in a vertical direction. That is, each of the first to third solder pads SP1 to SP3 may be formed at a position moved by a certain distance from a lower end portion of a corresponding through glass via in a horizontal direction, so as not to overlap a corresponding through glass via of the first to third through glass vias TGV1 to TGV3 in the vertical direction. An array structure of solder pads will be described below in detail.

An upper end portion of the first through glass via TGV1 may be electrically connected to a lower end portion of the fourth through glass via TGV4 formed in the second glass interposer 312 through a soldering process.

An upper end portion of the second through glass via TGV2 may be electrically connected to a lower end portion of the fifth through glass via TGV5 formed in the second glass interposer 312 through a soldering process.

An upper end portion of the third through glass via TGV3 may be electrically connected to one end portion of the first interposer redistribution layer IRDL1 formed between the first glass interposer 311 and the second glass interposer 312 through a soldering process.

An upper end portion of the fourth through glass via TGV4 may be electrically connected to a lower end portion of the seventh through glass via TGV7 formed in the third glass interposer 313 through a soldering process.

An upper end portion of the fifth through glass via TGV5 may be electrically connected to one end portion of the second interposer redistribution layer IRDL2 formed between the second glass interposer 312 and the third glass interposer 313 through a soldering process.

A lower end portion of the sixth through glass via TGV6 may be electrically connected to the other end portion of the first interposer redistribution layer IRDL1 through a soldering process, and an upper end portion thereof may be electrically connected to a lower end portion of the ninth through glass via TGV9 formed in the third glass interposer 313 through a soldering process. Also, an upper end portion of the ninth through glass via TGV9 may be electrically connected to the optical engine 320 through a soldering process.

A lower end portion of the seventh through glass via TGV7 may be electrically connected to one end portion of the third interposer redistribution layer IRDL3 formed on an upper surface of the third glass interposer 313 through a soldering process, and the other end portion of the third interposer redistribution layer IRDL3 may be electrically connected to the optical engine 320 through a soldering process.

A lower end portion of the eighth through glass via TGV8 may be electrically connected to the other end portion of the second interposer redistribution layer IRDL2 through a soldering process, and an upper end portion thereof may be electrically connected to the optical engine 320 through a soldering process.

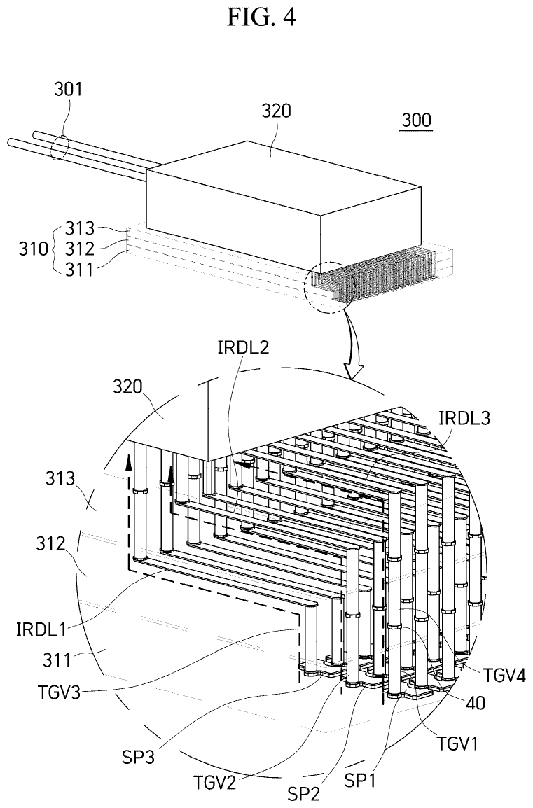

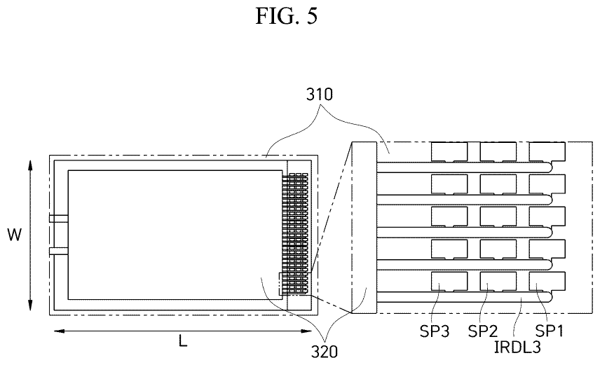

FIG. 4 is a perspective view illustrating an array structure of solder pads and a signal path of a surface-mount-type optical module in the signal path between the switch ASIC and the surface-mount-type optical module illustrated in FIG. 3, and FIG. 5 is a plan view of the array structure of the solder pads illustrated in FIG. 4 when seen from above.

Referring to FIGS. 4 and 5, as described above, the first to third solder pads SP1 to SP3 may be formed in a 2D array of a matrix form on the upper surface of the system board 100 and/or the lower surface of the first glass interposer 311 formed at the lowermost portion among the first to third glass interposers 311 to 313. In this case, when seen from above, each of the first to third solder pads SP1 to SP3 may be formed at a position offset by a predefined distance, so as not to overlap a corresponding through glass via of the first to third through glass vias TGV1 to TGV3 in the vertical direction. For example, the first solder pad SP1 may be formed at a position moved by a certain distance from a lower end portion of the first through glass via TGV1 in the horizontal direction, so as not to overlap the first through glass via TGV1 in the vertical direction. Also, when seen from above, the first to third solder pads SP1 to SP3 may be formed at a position offset by a predefined distance, so as not to overlap the third interposer redistribution layer IRDL3. In this case, the first to third through glass vias TGV1 to TGV3 may overlap the third interposer redistribution layer IRDL3 in the vertical direction.

As described above, when seen from above, because the solder pad SP is not covered by the interposer redistribution layer IRDL, the surface-mount-type optical module 300 may be bonded to the system board 100 through a soldering process using a laser beam. For example, a laser beam irradiated from an upper portion of the glass interposer 310 may pass through the glass interposer 310 and may reach the solder pad SP without interference of the interposer redistribution layer IRDL, and thus, laser energy absorbed by the solder pad SP may melt a solder bump to electrically and mechanically bond the surface-mount-type optical module 300 to the system board 100.

Although not clearly illustrated in FIGS. 1 to 5, a solder pad may be formed in a 2D array of a matrix form at a position corresponding to the solder pad SP formed on a lower surface of the glass interposer 310 of a stack structure in the upper surface of the system board 100. A system board-side solder pad and a glass interposer-side solder pad may be bonded to each other through melting of the solder bump.

Moreover, through glass vias (for example, TGV1 and TGV4 of FIG. 4) formed in the glass interposer 310 of a stack structure may be bonded to each other by using a high temperature solder bump (40 of FIG. 4), and a solder pad of a system board and a solder pad of a system board may be bonded to each other by using a low temperature solder bump. Here, the high temperature solder bump may denote a solder material which is melted within a first temperature range, and the low temperature solder bump may denote a solder material which is melted within a second temperature range which is lower than the first temperature range. The second temperature range being lower than the first temperature range may denote that a minimum limit of the first temperature range is greater than a maximum limit of the second temperature range.

The reason that a low temperature solder is used in bonding of the solder pads SP and a high temperature solder is used in bonding of the through glass vias TGV may be because a bonding process of the through glass vias (for example, TGV1 and TGV4 of FIG. 4) is performed before the surface-mount-type optical module 300 is mounted on a surface of the system board 100. Even when heat occurring in a laser soldering process performed subsequently is transferred to the high temperature solder (40 of FIG. 4), the high temperature solder (40 of FIG. 4) may be used so that a solidified high temperature solder is not again melted.

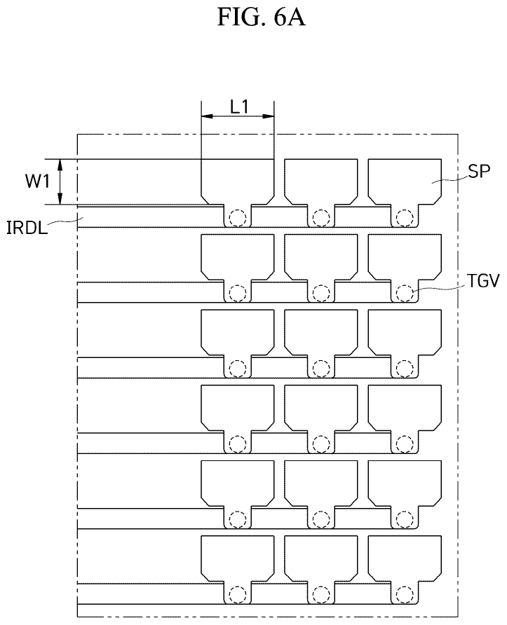

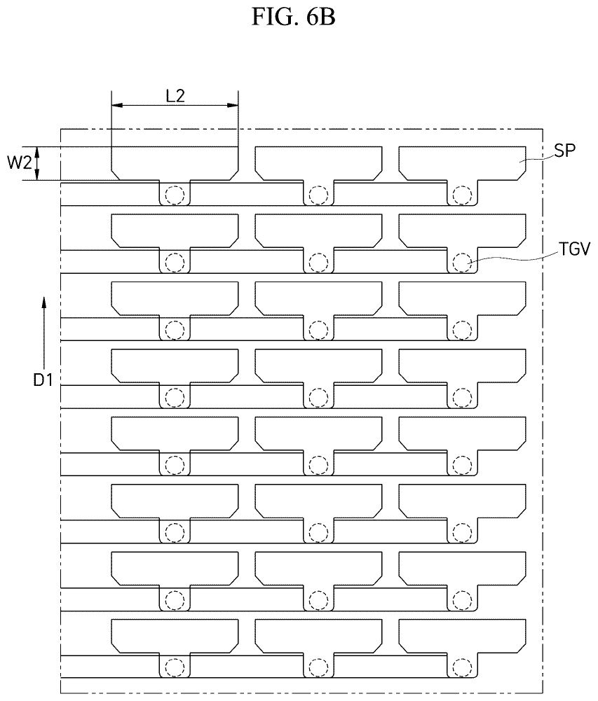

FIG. 6A is a plan view illustrating a solder pad of 3×6 array according to embodiments of the present disclosure, and FIG. 6B is a plan view illustrating a solder pad of 3×8 array according to embodiments of the present disclosure.

Referring to FIG. 6A, when seen from above, a solder pad SP of 3×6 array may be disposed in a 2D array structure of a matrix form at an offset position so as not to overlap a through glass via TGV and an interposer redistribution layer IRDL. Each solder pad may be formed in a tetragonal shape having a first length L1 and a first width W1.

Referring to FIG. 6B, when a length of each solder pad increases, and a width thereof decreases, the number of arrays of solder pads may increase in an array direction D1 of the interposer redistribution layer IRDL. In detail, in a 3×8 array, each solder pad SP may be formed in a tetragonal shape having a second length L2 which is longer than the first length L1 and a second width W2 which is shorter than the first width W1.

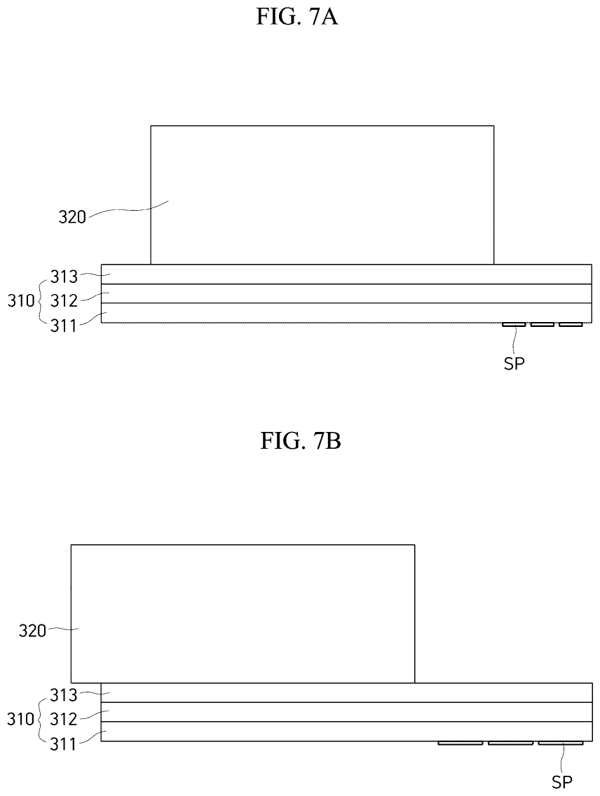

FIG. 7A is a side view illustrating a form where an optical engine is disposed on a glass interposer, based on a solder pad structure of 3×6 array illustrated in FIG. 6A, and FIG. 7B is a side view illustrating a form where an optical engine is disposed on a glass interposer, based on a solder pad structure of 3×8 array illustrated in FIG. 6B.

Referring to FIG. 7A, in a solder pad structure of 3×6 array, a lower surface of an optical engine 320 may be mounted at a reference position in an upper surface of a glass interposer 310 of a stack structure.

Referring to FIG. 7B, in a solder pad structure of 3×8 array, a length of a solder pad SP may increase, and a width thereof may decrease, and thus, more solder pads may be arranged in the same area. Particularly, as a length of the solder pad SP increases, the optical engine 320 may be mounted at a position spaced apart from the reference position in an opposite direction of the solder pad SP in a surface of the glass interposer 310.

In a case where the optical engine 320 is mounted on the surface of the glass interposer 310, if an electrical connection and mechanical fixing are secured, as illustrated in FIG. 7B, a portion of the optical engine 320 may protrude to an outer portion of the glass interposer 310.

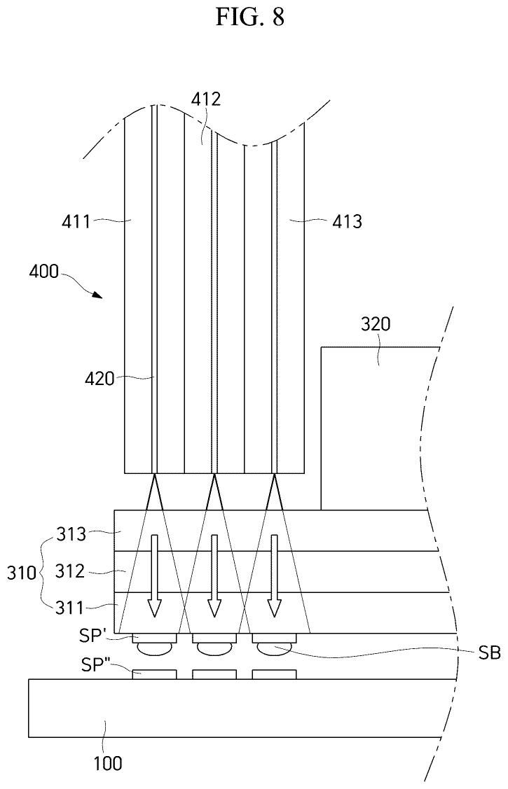

FIG. 8 is a side view for describing a bonding process between a system board and a surface-mount-type optical module according to embodiments of the present disclosure.

Referring to FIG. 8, the optical engine 320 may be mounted on a glass interposer 310, and a solder pad SP′ may be formed in a 2D array of a matrix form on a lower surface of the glass interposer 310. A solder pad SP″ may be formed at a position corresponding to the solder pad SP′ of the glass interposer 310 in a surface of a system board 100.

The solder pad SP′ formed in the glass interposer 310 and the solder pad SP″ formed in the glass interposer 310 may be electrically and mechanically bonded to each other by a solder bump SB which is melted in a soldering process using a multi-channel laser irradiation device 400.

The multi-channel laser irradiation device 400 may include a plurality of fiber array blocks 411 to 413, and a plurality of optical fibers 420 may be aligned and disposed in each of the plurality of fiber array blocks 411 to 413. For conciseness of the drawing, in FIG. 10, only one optical fiber 420 is illustrated in one fiber array block 411.

The multi-channel laser irradiation device 400 may output a plurality of laser beams in parallel in an upper portion of the glass interposer 310 to simultaneously irradiate the laser beams onto a plurality of solder pads, and thus, may locally and simultaneously heat the solder pads.

The optical fiber of the fiber array block 411 may be disposed at a position aligned in the solder pad SP′. At this time, a laser beam irradiated through an optical fiber may pass through the glass interposer 310 of a stack structure and may reach the solder pad SP′. Laser energy absorbed by the solder pad SP′ may locally heat a solder bump SB to melt the solder bump SB, and thus, the solder pad SP′ and the solder pad SP″ formed in the system board 100 may be bonded to each other.

Such a bonding process may enable a surface-mount-type optical module 300 to be bonded or detachably attached to the system board 100 by using a laser beam, and particularly, even when an individual optical module is broken down in the system board 100 to which CPO technology is applied, only an optical module may be selectively removed and replaced by locally irradiating a laser beam in a narrow work space.

As a result, an optical bonding structure according to embodiments of the present disclosure may enable the surface-mount-type optical module 300 including a solder pad of a 2D array to be stably mounted on the system board 100, and in a CPO environment where individual optical module replacement is difficult, the efficiency of maintenance/repair and the easiness of module replacement may be considerably enhanced.

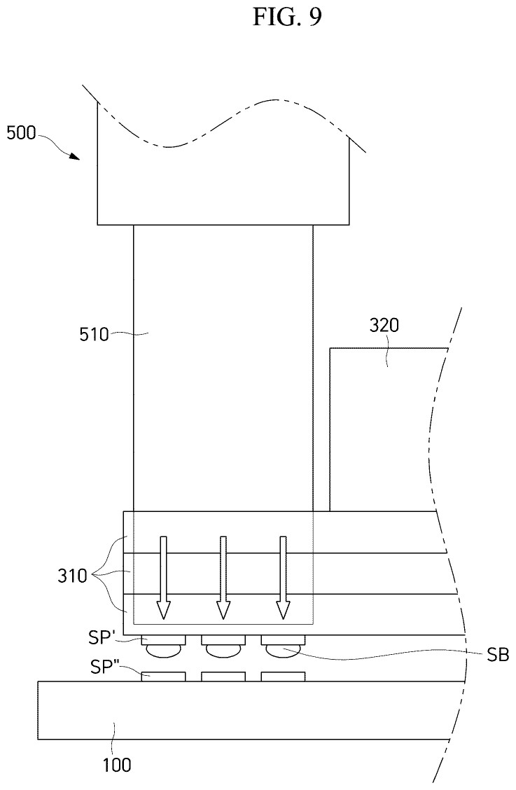

FIG. 9 is a side view for describing a bonding process between a system board and a surface-mount-type optical module according to other embodiments of the present disclosure.

Referring to FIG. 9, in a bonding process according to other embodiments of the present disclosure, a homogenized collimated laser beam irradiation system 500 which irradiates a homogenized collimated laser beam 50 onto an entire region where a plurality of solder pads SP′ are arranged may be used for heating and melting a solder bump SB. Such a configuration may be distinguished from the embodiment of FIG. 10 using the multi-channel laser irradiation device 400 which irradiates a plurality of laser beams onto individual solder pads in parallel.

In a case which uses the homogenized collimated laser beam 50, energy may be uniformly transferred to an entire solder bump, and thus, an over-melting or under-melting phenomenon may be prevented, and a local region may be uniformly heated.

Therefore, thermal treatment may be performed on an entire solder pad array or by specific line units, and a quality deviation between modules may be minimized based on a uniform beam distribution characteristic. Also, a wide area may be processed at a time, and thus, a process time may be shortened.

According to embodiments of the present disclosure, the implementation of high-density integration and the enhancement of maintenance/repair may be simultaneously accomplished in a CPO system environment, based on a laser soldering structure where a surface-mount-type optical module including a solder pad formed in a 2D array of a matrix form may be easily bonded to a system board.

Particularly, based on a solder pad structure arranged at an offset position and laser transmission through an optically-transparent glass interposer, a local heating process using a multi-channel laser beam or a homogenized collimated laser beam may be possible, and thus, the individual attachment/detachment and replacement of a surface-mount-type optical module may be precisely performed.

Therefore, only a specific optical module may be selectively removed and replaced in a narrow space without needing to replace a whole system board or a switch ASIC even when an optical module is broken down, and thus, OPEX and convenience for the maintenance/repair of a CPO system may be considerably enhanced.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A surface-mount-type optical module mounted on a system board, the surface-mount-type optical module comprising:
a glass interposer;
a plurality of solder pads formed in a two-dimensional (2D) array of a matrix form on a lower surface of the glass interposer and bonded to the system board; and
an optical engine mounted on the glass interposer and electrically connected to the plurality of solder pads by through glass vias and interposer redistribution layers formed in the glass interposer,
wherein each of the plurality of solder pads is formed at a position offset by a predefined distance in a horizontal direction not to overlap the through glass vias in a vertical direction.

2. The surface-mount-type optical module of claim 1, wherein each of the plurality of solder pads is formed at a position offset in the horizontal direction not to overlap the interposer redistribution layers in a vertical direction.

3. The surface-mount-type optical module of claim 1, wherein the plurality of solder pads are electrically and mechanically bonded to a surface of the system board by a plurality of solder bumps, and
a laser beam passing through the glass interposer reaches the plurality of solder pads without interference of the interposer redistribution layers, and laser energy absorbed by the plurality of solder pads melt the plurality of solder bumps to electrically and mechanically bond the plurality of solder pads to the system board.

4. The surface-mount-type optical module of claim 3, wherein the laser beam comprises a plurality of laser beams output in parallel.

5. The surface-mount-type optical module of claim 3, wherein the laser beam comprises a homogenized collimated laser beam output from a homogenized collimated laser beam irradiation system.

6. The surface-mount-type optical module of claim 3, wherein each of the plurality of solder bumps used for bonding the plurality of solder pads to the system board is a low temperature solder bump, and
each of the plurality of solder bumps used for bonding the through glass vias formed in the glass interposer is a high temperature solder bump.

7. The surface-mount-type optical module of claim 6, wherein the high temperature solder bump is melted within a first temperature range, and the low temperature solder bump is melted within a second temperature range which is lower than the first temperature range.

8. A co-packaged optics switch assembly comprising:
a system board;
a surface-mount-type optical module mounted on the system board; and
a switch application specific integrated circuit (ASIC) mounted on the system board and electrically connected to the surface-mount-type optical module by a redistribution layer and a through via formed in the system board,
wherein the surface-mount-type optical module comprises:
a glass interposer;
a plurality of solder pads formed in a two-dimensional (2D) array of a matrix form on a lower surface of the glass interposer and bonded to the system board; and
an optical engine mounted on the glass interposer and electrically connected to the plurality of solder pads by through glass vias and interposer redistribution layers formed in the glass interposer, and
each of the plurality of solder pads is formed at a position offset by a predefined distance in a horizontal direction not to overlap the through glass vias in a vertical direction.

9. The co-packaged optics switch assembly of claim 8, wherein each of the plurality of solder pads is formed at a position offset in the horizontal direction not to overlap the interposer redistribution layers in a vertical direction.

10. The co-packaged optics switch assembly of claim 8, wherein the plurality of solder pads are electrically and mechanically bonded to a surface of the system board by a plurality of solder bumps, and
a laser beam passing through the glass interposer reaches the plurality of solder pads without interference of the interposer redistribution layers, and laser energy absorbed by the plurality of solder pads melt the plurality of solder bumps to electrically and mechanically bond the plurality of solder pads to the system board.

11. The co-packaged optics switch assembly of claim 10, wherein the laser beam comprises a plurality of laser beams output in parallel.

12. The co-packaged optics switch assembly of claim 10, wherein the laser beam comprises a homogenized collimated laser beam output from a homogenized collimated laser beam irradiation system.

13. The co-packaged optics switch assembly of claim 10, wherein each of the plurality of solder bumps used for bonding the plurality of solder pads to the system board is a low temperature solder bump, and
each of the plurality of solder bumps used for bonding the through glass vias formed in the glass interposer is a high temperature solder bump.
